(19) United States
(12) Patent Application Publication
(10) Pub. No.: US 2009/0320918 A1
(43) Pub. Date: Dec. 31, 2009

(54) Photoelectric conversion device

(75) Inventors: Masahiro Tsuchiya, Tokyo (JP); Tokuhiko Handa, Tokyo (JP); Atsushi Monden, Tokyo (JP); Junji Tanabe, Tokyo (JP); Masahiro Shinkai, Tokyo (JP)

Correspondence Address: OLIFF & BERRIDGE, PLC, P.O. BOX 320850, ALEXANDRIA, VA, 22320-4850, US

(73) Assignee: TDK CORPORATION, TOKYO (JP)

(21) Appl. No.: 12/457,686

(22) Filed: Jun. 18, 2009

(30) Foreign Application Priority Data
Jun. 25, 2008 (JP) 2008-165827

(51) Int. Cl. H01L 31/00

(52) U.S. Cl. 136/256

(57) ABSTRACT

The present invention provides a photoelectric conversion device capable of improving durability without using particular material. The photoelectric conversion device includes a working electrode in which dye is carried by a metal oxide semiconductor layer and a facing electrode having a conductive layer, and a semi-solid electrolyte containing layer supported between the working electrode and the facing electrode. The electrolyte containing layer contains an electrolyte solution in which a solid electrolyte salt is dissolved in an organic solvent, and a particle. Thereby, liquid leakage or the like hardly occurs even under a high-temperature environment in comparison with the case where the electrolyte containing layer does not contain a particle.

### BACKGROUND OF THE INVENTION

1. Field of the Invention

The present invention relates to a photoelectric conversion device using dye.

2. Description of the Related Art

A dye-sensitized photoelectric conversion device using dye as photosensitizer has been known as a photoelectric conversion device for a solar cell or the like which converts light energy such as sun light into electric energy. This dye-sensitized photoelectric conversion device is theoretically expected to have high efficiency, and it is considered that the dye-sensitized photoelectric conversion device is more advantageous in terms of cost in comparison with a widely-distributed photoelectric conversion device using a silicon semiconductor. Therefore, the dye-sensitized photoelectric conversion device has attracted attention as a photoelectric conversion device for the next generation, and the development has been in progress for practical use.

The dye-sensitized photoelectric conversion device generates electricity by utilizing that dye has characteristics to absorb light and emit an electron. The dye-sensitized photoelectric conversion device has an electrochemical cell structure via an electrolyte. Specifically, the dye-sensitized photoelectric conversion device has such a configuration that a porous layer is formed by burning an oxide semiconductor such as titanium oxide, and a working electrode which absorbs dye, and a facing electrode as a counter electrode are adhered with an electrolyte in between. As the electrolyte (so-called redox electrolyte), an electrolyte solution (liquid electrolyte) in which an electrolyte salt is dissolved in an organic solvent is typically used.

However, in such a dye-sensitized photoelectric conversion device, it is difficult to say that sufficient conversion efficiency is achieved. For the purpose of improving the conversion efficiency, various approaches are considered. Specifically, there has been known a technique in which, as an electrolyte solution containing an iodine ion, cyanoethylated polysaccharide is added to ionic liquid and an organic solvent (refer to Japanese Unexamined Patent Publication No. 2008-010189). Moreover, there has been known a technique in which a conductive layer is formed on a surface of a counter electrode by using mixture of carbon material and a conductive polymer so as to increase an area where an electrolyte solution and the conductive layer are in contact with each other (refer to Japanese Unexamined Patent Publication No. 2004-337530).

### SUMMARY OF THE INVENTION

However, in the case where the above-described electrolyte solution is used, there is a risk of occurrence of liquid leakage or the like, and it is difficult to assure high durability.

In view of the foregoing, it is desirable to provide a photoelectric conversion device capable of improving durability without using particular material such as ionic liquid.

According to an embodiment of the present invention, there is provided a photoelectric conversion device including: an electrode including a carrying layer which carries dye; and a semi-solid electrolyte containing layer formed on the carrying layer. The electrolyte containing layer contains an electrolyte solution and a particle, the electrolyte solution being formed by dissolving at least a solid electrolyte salt in the organic solvent. Here, the term “semi-solid” means the state with high fluidity like liquid and the state different from the state of no fluidity like solid, and indicates a wide concept including, for example, paste. Here, the term “solid electrolyte salt” means one having a melting point of 100° C. or more, and at least partially ionizing by being dissolved in the organic solvent.

In the photoelectric conversion device according to the embodiment of the present invention, when the dye carried by the carrying layer is subjected to light, the dye erected by absorbing the light injects an electron to the carrying layer, and the electron travels to an external circuit. Meanwhile, in the electrolyte containing layer, with the travel of the electron, a redox reaction (oxidation-reduction reaction) is repeated so that the oxidized dye returns (is reduced) to a ground state. Thereby, the continuous travel of the electron occurs in the photoelectric conversion device, and the photoelectric conversion is constantly performed. Here, leakage and scattering of the electrolyte solution are suppressed even under a high-temperature environment, since the semi-solid electrolyte containing layer contains the electrolyte solution and the particle, and the particle serves as liquid retaining material.

In the photoelectric conversion device according to the embodiment of the present invention, content of the particle in the electrolyte containing layer is preferably 5 weight % or more and 60 weight % or less. Within this range, the electron more favorably travels while suppressing liquid leakage or the like from the electrolyte containing layer. The particle preferably contains carbon particles. Thereby, conductivity of the electrolyte containing layer improves and the redox reaction is favorably performed in the electrolyte containing layer so that the electron more quickly travels and an amount of discharge to an amount of light absorbed by the dye more increases. In this case, bulk resistance of the carbon particle is preferably 10 Ωcm, i.e., 0.1 Ωm, or less. Carbon black may be used as the carbon particle. Here, the term “carbon particle” means particulate material containing carbon as a major component. For example, there is graphite, carbon black, carbon nanotube, or graphene. The term “bulk resistance” means resistance in bulk of a particle.

In the photoelectric conversion device according to the embodiment of the present invention, content of the solid electrolyte salt in the electrolyte solution is preferably 0.13 mol/dm³ or more and 0.75 mol/dm³ or less. Thereby, the electron more quickly travels in the electrolyte containing layer, and the amount of discharge to the amount of light absorbed by the dye more increases. In this case, the organic solvent may have one or more of a nitrile group, a carbonate ester structure, a cyclic ester structure, a lactam structure, an amide group, an alcohol group, a sulfinyl group, a pyridine ring, and a cyclic ether structure as a functional group. The organic solvent may contain one or more of methoxypropionitrile, propylene carbonate, N-methylpyrrolidone, pentanol, quinoline, N,N-dimethylformamide, γ-butyl lactone, dimethyl sulfoxide, 1,4-dioxane, methoxyacetonitrile, and butylnitrile.

In the photoelectric conversion device according to the embodiment of the present invention, the solid electrolyte salt may contain an iodide ion as an anion. The solid electrolyte salt may contain a quaternary ammonium ion as a cation.

In the photoelectric conversion device according to the embodiment of the present invention, since the semi-solid electrolyte containing layer contains an electrolyte solution and a particle, the electrolyte solution being formed by dissolving at least a solid electrolyte salt in the organic solvent, durability improves without using particular material in comparison with the case where the electrolyte containing layer does not contain a particle. The durability and the conversion efficiency improve, when content of the particle in the electrolyte containing layer is 5 weight % or more and 60 weight % or less. In particular, the conversion efficiency more improves when the particle contains carbon particles. Moreover, the conversion efficiency becomes higher, when content of the solid electrolyte salt in the electrolyte solution is 0.13 mol/dm³ or more and 0.75 mol/dm³ or less.

Other and further objects, features and advantages of the invention will appear more fully from the following description.

### BRIEF DESCRIPTION OF THE DRAWINGS

FIG. 1 is a cross-sectional view illustrating the configuration of a photoelectric conversion device according to an embodiment of the present invention.

FIG. 2 is an enlarged cross-sectional view selectively illustrating a main part of the photoelectric conversion device illustrated in FIG. 1.

### DETAILED DESCRIPTION OF THE PREFERRED EMBODIMENT

A preferred embodiment (hereinafter, simply referred to as an embodiment) of the present invention will be described in detail with reference to the accompanying drawings.

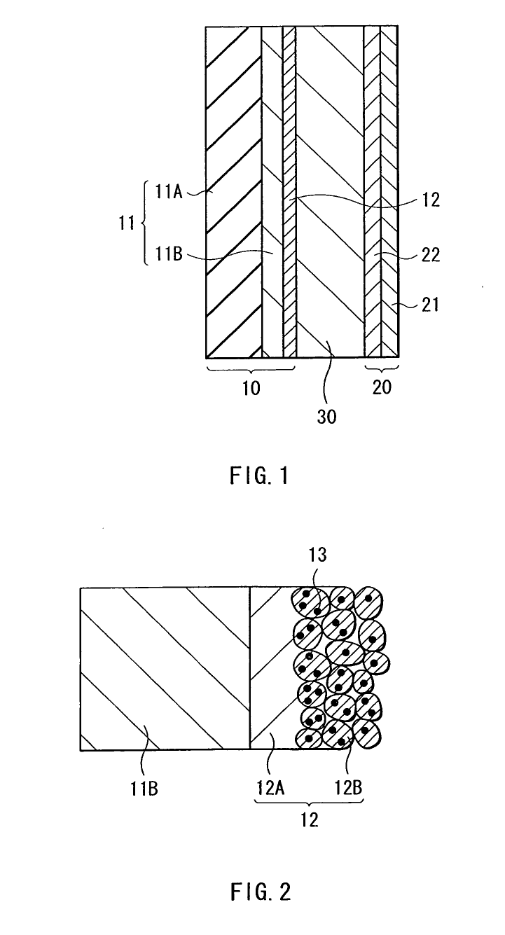

FIG. 1 schematically illustrates the cross-sectional configuration of a photoelectric conversion device according to an embodiment of the present invention. FIG. 2 selectively illustrates a main part of the photoelectric conversion device illustrated in FIG. 1 in an enlarged manner. The photoelectric conversion device illustrated in FIGS. 1 and 2 is a main part of a so-called dye-sensitized solar cell. This photoelectric conversion device includes a working electrode 10 and a facing electrode 20 facing each other with an electrolyte containing layer 30 in between. In the working electrode 10 and the facing electrode 20, only the working electrode 10, or both of the working electrode 10 and the facing electrode 20 have light transmittance.

The working electrode 10 includes, for example, a conductive substrate 11, a metal oxide semiconductor layer 12 arranged on one of the faces (face on the facing electrode 20 side) of the conductive substrate 11, and a dye 13 carried by the metal oxide semiconductor layer 12 serving as a carrying layer. The working electrode 10 functions as a negative electrode to an external circuit. For example, the conductive substrate 11 is provided with a conductive layer 11B which is arranged on the surface of an insulating substrate 11A, and the conductive layer 11B is in contact with the metal oxide semiconductor layer 12.

The substrate 11A is made of, for example, insulating material having light transmittance such as glass, plastic, and a transparent polymer film. As the transparent polymer film, for example, there is tetraacetyl cellulose (TAC), polyethylene terephthalate (PET), polyethylene naphthalate (PEN), syndiotactic polystyrene (SPS), polyphenylene sulfide (PPS), polycarbonate (PC), polyarylate (PAR), polysulfone (PSF), polyester sulfone (PES), polyetherimide (PEI), cyclic polyolefin, or phenoxy bromide.

The conductive layer 11B is made of, for example, conductive material having light transmittance such as indium oxide, tin oxide, indium-tin composite oxide (ITO), or fluorine-doped tin oxide (FTO: F—SnO₂).

The conductive substrate 11 may have, for example, a single-layer structure with conductive material. In that case, as material for the conductive substrate 11, for example, there is conductive material having light transmittance such as indium oxide, tin oxide, indium-tin composite oxide, or fluorine-doped tin oxide.

The metal oxide semiconductor layer 12 is a carrying layer carrying the dye 13, and, for example, has a porous structure as illustrated in FIG. 2. The metal oxide semiconductor layer 12 having the porous structure is formed with, for example, a dense layer 12A and a porous layer 12B. The dense layer 12A is formed in the interface between the conductive substrate 11 and the metal oxide semiconductor layer 12. It is preferable that the dense layer 12A be dense, and have few air gaps and a film shape. The porous layer 12B is formed on the facing electrode 20 side. It is preferable that the porous layer 12B have multiple air gaps, and a large surface area. In particular, it is preferable that the porous layer 12B have a structure in which a porous particle is attached on the porous layer 12B. The metal oxide semiconductor layer 12 may be formed, for example, in a porous structure with a single-layer structure.

The metal oxide semiconductor layer 12 contains one or a plurality of types of metal oxide semiconductor material. As the metal oxide semiconductor material, for example, there is titanium oxide, zinc oxide, tin oxide, niobium oxide, indium oxide, zirconium oxide, tantalum oxide, vanadium oxide, yttrium oxide, aluminum oxide, or magnesium oxide. The metal oxide semiconductor material may contain one type of material or composite material (mixture, mixed crystal, solid solution, or the like) of a plurality of types of materials. Among them, one or more of titanium oxide and zinc oxide are preferable.

The dye 13 is carried by the metal oxide semiconductor layer 12. The dye 13 is excited by absorbing light, and contains one or a plurality of types of dye capable of injecting an electron to the metal oxide semiconductor layer 12. It is preferable that this dye have, for example, an electron-withdrawing substituent which may be chemically combined with the metal oxide semiconductor layer 12. As the dye, for example, there is an organic dye such as cyanine dye, merocyanine disazo dye, trisazo dye, anthraquinone dye, polycyclic quinone dye, indigo dye, diphenylmethane dye, trimethylmethane dye, quinoline dye, benzophenone dye, naphthoquinone dye, perylene dye, fluorenone dye, squarylium dye, azulenium dye, perinone dye, quinacridone dye, metal-free phthalocyanine dye, or metal-free porphyrin dye.

As the dye, for example, there is also an organic metal complex compound, which is exemplified by an organic metal complex compound having both of ionic coordinate bond and nonionic coordinate bond, the ionic coordinate bond formed by a nitrogen anion and a metallic cation in an aromatic heterocycle and the nonionic coordinate bond formed between a nitrogen atom or a chalcogen atom, and a metallic cation, and an organic metal complex compound having both of ionic coordinate bond and nonionic coordinate bond, the ionic coordinate bond formed by an oxygen anion or a sulfur anion, and a metallic cation, and the nonionic coordinate bond formed between a nitrogen atom or a chalcogen atom, and a metallic cation. Specifically, for example, there is metallic phthalocyanine dye such as copper phthalocyanine or titanyl phthalocyanine, metallic naphthalocyanine dye, metallic porphyrin dye, or a ruthenium complex such as a bipyridyl ruthenium complex, a terpyridyl ruthenium complex, a phenanthroline ruthenium complex, a bicinchonic acid ruthenium complex, an azo ruthenium complex, or a quinolinol ruthenium complex.

As the above-described organic dye or organic metal complex compound, for example, there are a series of compounds represented by Chemical formula 1 to Chemical formula 3. In addition to these compounds, there is eosin Y, dibromofluorescein, fluorescein, rhodamine B, pyrogallol, dichlorofluorescein, erythrosine B (erythrosine is a registered trademark), fluorescein, or mercurochrome.

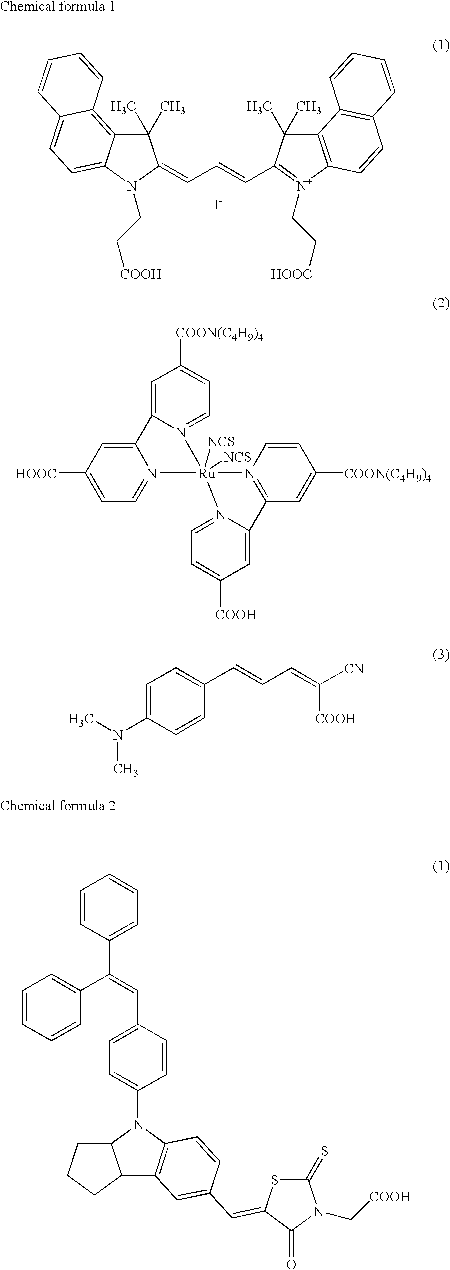

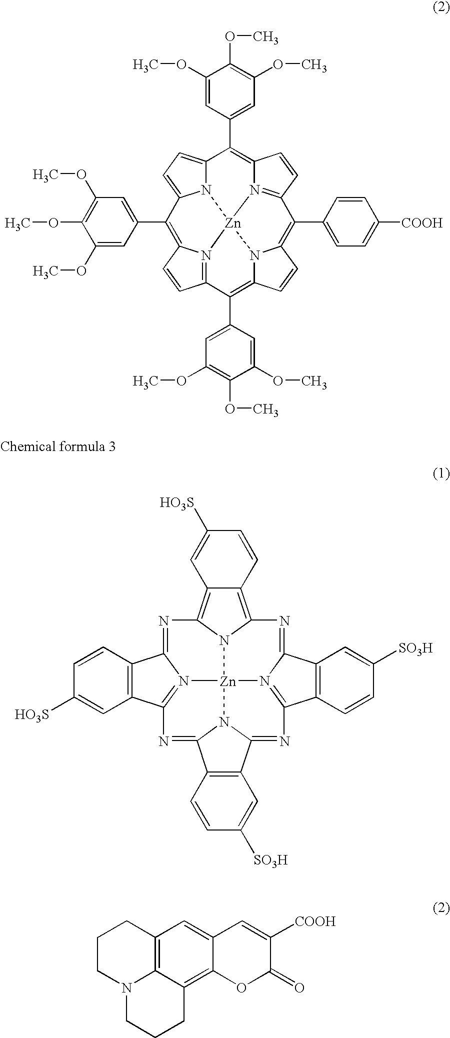

The facing electrode 20 is, for example, provided with a conductive layer 22 which is arranged on a conductive substrate 21. The conductive layer 22 is in contact with the electrolyte containing layer 30. The facing electrode 20 functions as a positive electrode to an external circuit. As material for the conductive substrate 21, for example, there is material similar to that for the conductive substrate 11 in the working electrode 10. As conductive material used for the conductive layer 22, for example, there is metal such as platinum (Pt), gold (Au), silver (Ag), copper (Cu), rhodium (Rh), ruthenium (Ru), aluminum (Al), magnesium (Mg), molybdenum (Mo), or indium (In), carbon (C), or a conductive polymer. The conductive material may be singularly used, or plurally used by mixing them. If necessary, for example, acrylic resin, polyester resin, phenol resin, epoxy resin, cellulose, melamine resin, fluoroelastomer, or polyimide resin may be used as bond material. The facing electrode 20 may, for example, have a single-layer structure of the conductive layer 22.

The electrolyte containing layer 30 is a redox electrolyte. The electrolyte containing layer 30 contains an electrolyte solution which contains an organic solvent and an electrolyte salt, and a particle, and is in a semi-solid state. Thereby, the particle serves as liquid retaining material, and liquid leakage or the like is suppressed even under a high-temperature environment without using particular material, in comparison with the case where a liquid electrolyte (electrolyte solution) containing no particle is used. Therefore, the durability improves and the safety is assured.

The electrolyte solution contains one or a plurality of types of organic solvents. Although the organic solvent is arbitrarily selected as long as it is electrochemically inactive and may dissolve a solid electrolyte salt which will be described later, the organic solvent preferably has a melting point of 20° C. or less, and a boiling point of 80° C. or more. When the melting point and the boiling point are within the above temperature ranges, the high durability is achieved. Moreover, the organic solvent preferably has high viscosity and high electric conductivity due to the following. The boiling point increases with the high viscosity, and thus leakage of the electrolyte is suppressed even under a high-temperature environment. The high conversion efficiency is achieved with the high electric conductivity. It is preferable that such an organic solvent have one or more of a nitrile group, a carbonate ester structure, a cyclic ester structure, a lactam structure, an amide group, an alcohol group, a sulfinyl group, a pyridine ring, and a cyclic ether group as a functional group. Thereby, the high efficiency is achieved in comparison with the case of containing no such functional group. As the organic solvent having such functional group, for example, there is acetonitrile, propylnitrile, butylnitrile, methoxyacetonitrile, methoxypropionitrile, dimethyl carbonate, ethyl methyl carbonate, ethylene carbonate, propylene carbonate, N-methylpyrrolidone, pentanol, quinoline, N,N-dimethylformamide, γ-butyl lactone, dimethyl sulfoxide, or 1,4-dioxane. Among them, one or more of methoxypropionitrile, propylene carbonate, N-methylpyrrolidone, pentanol, quinoline, N,N-dimethylformamide, γ-butyl lactone, dimethyl sulfoxide, 1,4-dioxane, methoxyacetonitrile, and butylnitrile are preferable.

Here, the solid electrolyte salt has a melting point of 100° C. or more, and at least a part of the solid electrolyte salt is dissolved in the electrolyte solution. Thereby, the conversion efficiency improves, for example, in comparison with the case where ionic liquid which will be described later is used as the electrolyte solution. As such a solid electrolyte salt, for example, there is cesium halide, quaternary ammonium halide, imidazolium halide, thiazolium halide, oxazolium halide, quinolinium halide, or pyridinium halide. These may be singularly used or plurally used by mixing them. Among them, as the solid electrolyte salt, an iodide salt having an iodide ion as an anion, or a quaternary ammonium salt having a quaternary ammonium ion as a cation is preferable. In particular, a quaternary ammonium iodide salt is preferable, because it is easily available, and the high conversion efficiency is achieved. As the iodide salt, for example, there is cesium iodide, tetraethylammonium iodide, tetrapropylammonium iodide, tetrabutylammonium iodide, tetrapentylammonium iodide, tetrahexylammonium iodide, tetraheptylammonium iodide, trimethylphenylammonium iodide, 3-methylimidazolium iodide, 1-propyl-2,3-dimethylimidazolium iodide, 3-ethyl-2-methyl-2-thiazolium iodide, 3-ethyl-5-(2-hydroxyethyl)-4-methylthiazolium iodide, 3-ethyl-2-methylbenzothiazolium iodide, 3-ethyl-2-methyl-benzoxazolium iodide, or 1-ethyl-2-methylquinolinium iodide. These may be singularly used, or plurally used by mixing them. Among them, a quaternary alkylammonium iodide salt such as tetraethylammonium iodide, tetrapropylammonium iodide, or tetrabutylammonium iodide is preferable.

The content (molar concentration) of the solid electrolyte salt in the electrolyte solution is preferably 0.13 mol/dm³ or more and 0.75 mol/dm³ or less, and more preferably 0.25 mol/dm³ or more and 0.75 mol/dm³ or less. Thereby, the higher conversion efficiency is achieved in comparison with the case where the content is out of the above-described range.

In addition to the above-described solid electrolyte salt, the electrolyte solution may contain one or a plurality of types of ionic liquid as other electrolyte salts. Here, the ionic liquid is one having a melting point of 100° C. or less. Such ionic liquid includes one usable for a battery cell, a solar battery cell, and the like. Examples of the ionic liquid are disclosed in “Inorg. Chem” 1996, 35, p. 1168 to p. 1178, “Electrochemistry” 2002, 2, p. 130 to p. 136, Published Japanese Translation of the PCT Patent Application No. Hei-9-507334, Japanese Unexamined Patent Publication No. Hei-8-259543, and the like. Among them, as the ionic liquid, a salt having a melting point lower than a room-temperature (25° C.), or a salt having a melting point higher than the room-temperature but is liquefiable at the room-temperature by dissolving with other electrolyte salts or the like is preferable. As the ionic liquid, for example, there is one containing an anion and a cation which will be described below.

As the cation in the ionic liquid, for example, there is ammonium, imidazolium, oxazolium, thiazolium, oxadiazolium, triazolium, pyrrolidinium, pyridinium, piperidinium, pyrazolium, pyrimidinium, pyrazinium, triazinium, phosphonium, sulfonium, carbazolium, indolium, or derivatives thereof. These may be singularly used or plurally used by mixing them. Among them, one or more of ammonium, imidazolium, pyridinium, piperidinium, pyrazolium, sulfonium and derivatives thereof are preferable. In particular, imidazolium is preferable. Specifically, 1-methyl-3-propylimidazolium, 1-butyl-3-methylimidazolium, 1,2-dimethyl-3-propylimidazolium, or 1-ethyl-3-methylimidazolium is preferable, because they are easily available, and the high durability and high conversion efficiency are achieved with them.

As the anion in the ionic liquid, there is metallic chloride such as AlCl₄— or Al₂Cl₇—, a fluorine compound ion such as PF₆—, BF₄—, CF₃SO₃—, N(CF₃SO₂)₂—, F(HF)ₙ—, or CF₃COO—, a non-fluorine compound ion such as NO₃—, CH₃COO—, C₆H₁₁COO—, CH₃OSO₃—, CH₃OSO₂—, CH₃SO₃—, CH₃SO₂—, (CH₃O)₂PO₂—, N(CN)₂—, or SCN—, or a halide compound ion such as iodine or bromine. These may be singularly used or plurally used by mixing them. Among them, as the anion, an iodide ion is preferable.

In addition to those described above, the electrolyte solution may contain additive or the like. As the additive, for example, there is simple halogen. As the simple halogen, for example, there is iodine (I₂) or bromine (Br₂). In the electrolyte containing layer 30, in the case where a particle which does not have a catalytic ability for the redox reaction (will be described later) is used, it is necessary for the electrolyte containing layer 30 to contain simple halogen to obtain device characteristics such as the sufficient conversion efficiency.

The particle is supporting material to make the electrolyte containing layer 30 into a semi-solid state, and serves as liquid retaining material so that the durability improves. The particle is arbitrarily selected as long as it favorably maintains the device characteristics such as the conversion efficiency. As the particle, for example, there are a particle having conductivity, semi-conductivity or insulating properties, a particle catalyzing the redox reaction, and the like. These may be singularly used, or plurally used by mixing them. Among them, the particle having conductivity (conductive particle) is preferable, the particle catalyzing the redox reaction is more preferable, and the particle having conductivity and catalyzing the redox reaction is particularly preferable. In the case where the particle has conductivity, the electric resistance of the electrolyte containing layer 30 is reduced, and the electron quickly travels. Moreover, it is thought that deposition of the electrolyte solution due to generation of unexpected electromotive force is suppressed. In the case where the particle catalyzes the redox reaction, the redox reaction is favorably performed in the electrolyte containing layer 30. Therefore, in both of the case where the particle has conductivity, and the case where the particle catalyzes the redox reaction, the durability and the conversion efficiency improve. In the case where the particle has conductivity and catalyzes the redox reaction, particularly high efficiency is achieved.

As constituent material of the particle, for example, there is carbon material, titanium oxide (TiO₂), silica gel (silicon oxide; SiO₂), zinc oxide (ZnO), tin oxide (SnO₂), cobalt titanium oxide (CoTiO₃), or barium titanium oxide (BaTiO₂). These may be singularly used, or plurally used by mixing them. Among them, as the particle, a carbon particle containing carbon material as constituent material is preferable. This is because the carbon particle has conductivity and catalyzes the redox reaction so that high efficiency is achieved. It is preferable that the carbon particle have high conductivity, and a large specific surface area. Thereby, the conductivity of the electrolyte containing layer 30 becomes high, and the area where the electrolyte containing layer 30 and the electrolyte solution are in contact with each other becomes large so that the redox reaction is more favorably catalyzed. As the conductivity of the carbon particle, it is preferable that bulk resistance of the carbon particle be 10 Ωcm (=0.1 Ωm) or less. Thereby, the electric resistance of the electrolyte containing layer 30 is sufficiently suppressed, and the internal resistance of the device is also sufficiently suppressed. For more detail, in the dye-sensitized photoelectric conversion device, the resistance of the constituent material is typically one of the major factors for the loss of the conversion efficiency. In particular, the conductive material having light transmittance and used for the conductive substrate has relatively-high electric resistance. For example, FTO (F—SnO₂) has resistance of approximately 10 Ωcm. For this reason, in the case where a carbon particle is used as the particle, when a carbon particle having resistance lower than that of the conductive material is used, the conductive material having light transmittance such as FTO used as the constituent material of the conductive layer 11B, that means, when a carbon particle having bulk resistance of 10 Ωcm or less is used, the internal resistance of the device is suppressed low, and the sufficient conversion efficiency is achieved.

As such a carbon particle, for example, there is graphite which is crystalline, or activated carbon or carbon black which is amorphous. In addition to these, there is graphene, carbon nanotube, fullerene, or the like. These may be singularly used, or plurally used by mixing them. As the graphite, there are artificial graphite, natural graphite, and the like. As the carbon black, there are furnace black, oil furnace, channel black, acetylene black, thermal black, ketjen black, and the like. As the carbon particle, carbon black is particularly preferable, because the high efficiency is achieved. As the carbon black, one having high DBP-absorption (JIS K6217-4) is preferable. Thereby, the absorption of the electrolyte solution per unit particle increases, and it is thought that this contributes to the improvement of the conversion efficiency.

The particle content in the electrolyte containing layer 30 is preferably high, since the durability improves and the conversion efficiency is favorably maintained. However, it is preferable that the particle content be 5 weight % or more and 80 weight % or less. Within this range, appropriate fluidity is held, and squeegee and applying in screen-printing becomes easy at the time of forming the electrolyte containing layer 30. It is more preferable that the particle content be 5 weight % or more and 70 weight % or less. Within this range, miscibility (dispersibility) of the particle and the electrolyte solution improves, and adjustment of the mixture (paste) of the electrolyte solution and the particle used for forming the electrolyte containing layer 30 is easily performed. Moreover, it is preferable that the particle content be 5 weight % or more and 60 weight % or less, and more preferable that the particle content be 10 weight % or more and 60 weight % or less. Within the range from 5 weight % to 60 weight %, the durability and the conversion efficiency improve. Within the range from 10 weight % to 60 weight %, the higher conversion efficiency is achieved.

In addition to the above-described electrolyte solution and particle, the electrolyte containing layer 30 may contain, for example, a polymer compound. As the polymer compound, for example, there is fluorine polymer such as polyvinylidene floride or copolymer of vinylidene fluoride and hexafluoropropylene, p-type conductive polymer such as polyaniline, polyacetylene, polypyrrole, polythiophene, polyphenylene, polyphenylenevinylene, or derivatives thereof, or p-doped polymer in which a part of conductive polymer is doped with an anion such as a sulfonate ion.

The photoelectric conversion device may be manufactured, for example, with a manufacturing method described below.

The working electrode 10 is manufactured. First, the metal oxide semiconductor layer 12 having the porous structure is formed by electrolytic deposition or baking method on the face where the conductive layer 11B in the conductive substrate 11 is formed. In the case where the metal oxide semiconductor layer 12 is formed by electrolytic deposition, for example, electrolytic deposition is performed in the following way. An electrolytic bath containing a metallic salt is set at a predetermined temperature while the electrolytic bath is bubbled with oxygen and air. The conductive substrate 11 is dipped in the electrolytic bath with a predetermined voltage applied between the conductive substrate 11 and a counter electrode, and thereby the metal oxide semiconductor layer 12 is formed. In that case, the counter electrode may be appropriately exercised in the electrolytic bath. In the case where the metal oxide semiconductor layer 12 is formed by baking method, for example, baking method is performed in the following way. Powder of a metal oxide semiconductor is dispersed in sol of a metal oxide semiconductor to obtain metal oxide slurry. The metal oxide slurry is applied to the conductive substrate 11 and dried, and then burned. Thereby, the metal oxide semiconductor layer 12 is formed. Next, the conductive substrate 11 on which the metal oxide semiconductor layer 12 is formed is dipped in a dye solution in which the dye 13 is dissolved in an organic solvent, and the dye 13 is carried by the metal oxide semiconductor layer 12. Next, if necessary, a protective layer may be formed by applying a solution containing ionic liquid on the metal oxide semiconductor layer 12 which carries the dye 13. The protective layer is for suppressing physical damage such as destruction of the metal oxide semiconductor layer 12 and peeling of the dye 13 which may occur at the time of forming the electrolyte containing layer 30 as will be described later. At this time, the solution may be applied under vacuum atmosphere. Alternatively, an organic solvent or the like may be applied to improve wettability of the surface of the metal oxide semiconductor layer 12, and then the solution containing the ionic liquid may be applied. Needless to say, the solution containing the ionic liquid may be applied in several times. The solution containing the ionic liquid means liquid containing ionic liquid, and it may be simple ionic liquid, or may be a solution in which ionic liquid is dissolved in a solvent.

Next, for example, the facing electrode 20 is manufactured by forming the conductive layer 22 on one surface of the conductive substrate 21. The conductive layer 22 is formed, for example, by sputtering conductive material.

Next, a solid electrolyte salt is dissolved in the organic solvent and additive or the like is added if necessary so that the above-described electrolyte solution is adjusted. After that, a particle is mixed and dispersed in the electrolyte solution. Thereby, paste for forming the semi-solid electrolyte containing layer 30 is manufactured.

Finally, the above-described paste is applied on the metal oxide semiconductor layer 12 carrying the dye 13 in the working electrode 10. The face carrying the dye 13 in the working electrode 10, and the face where the conductive layer 22 in the facing electrode 20 is formed face each other to maintain a predetermined space in between, and are adhered with a spacer such as sealant (not illustrated in the figure). Then, by sealing the whole, the electrolyte containing layer 30 is formed. Thereby, the photoelectric conversion device as illustrated in FIGS. 1 and 2 is completed.

In the photoelectric conversion device, when the dye 13 carried by the working electrode 10 is subjected to light (sunlight or visible light at the same level as the sunlight), the dye 13 is erected by absorbing the light and injects an electron to the metal oxide semiconductor layer 12. The electron travels to the conductive layer 11B which is immediately adjacent to the metal oxide semiconductor layer 12, and reaches the facing electrode 20 through the external circuit. On the other hand, in the electrolyte containing layer 30, a redox electrolyte is oxidized so that the dye 13 oxidized with the travel of the electron returns (is reduced) to a ground state. This oxidized electrolyte is reduced by receiving the above-described electron. In this manner, the travel of the electron between the working electrode 10 and the facing electrode 20, and the redox reaction in the electrolyte containing layer 30 accompanied by the travel of the electron are repeated. Thereby, the continuous travel of the electron occurs, and the photoelectric conversion is constantly performed.

In the photoelectric conversion device, since the semi-solid electrolyte containing layer 30 contains the electrolyte solution in which at least the solid electrolyte salt is dissolved in the organic solvent, and the particle, for example, leakage and scattering of the electrolyte solution is suppressed even under a high-temperature environment in comparison with the case where liquid electrolyte (electrolyte solution) containing no particle is used. Therefore, the durability improves without using particular material such as ionic liquid which is generally said to be more costly in comparison with material (such as an organic solvent and a solid electrolyte salt) used for an electrolyte solution. In this case, when the particle content in the electrolyte containing layer 30 is 5 weight % or more and 60 weight % or less, the durability improves and the high conversion efficiency is achieved.

When a carbon particle is used as the particle, and particularly when carbon black is used as the particle, the conductivity of the electrolyte containing layer 30 improves, and the redox reaction is favorably performed in the electrolyte containing layer 30. In this case, since the carbon material constituting the carbon particle catalyzes the redox reaction in the electrolyte containing layer 30, it is unnecessary to use costly material such as typically-used platinum as the constituent material of the conductive layer 22 in the facing electrode 20. Therefore, the cost may be reduced.

When the content of the solid electrolyte salt in the electrolyte solution is 0.13 mol/dm³ or more and 0.75 mol/dm³ or less, the conversion efficiency is favorably maintained.

### EXAMPLES

Before describing specific examples of the present invention, reference examples to the examples will be described.

### Reference Examples 1 to 4

Instead of the electrolyte containing layer 30, mixture of an electrolyte solution and a particle with composition indicated in Table 1 which will be described later was used, and a simple cell having a configuration as illustrated in FIG. 1 was manufactured through steps described below.

Specifically, instead of the working electrode, a first substrate in which a metal oxide semiconductor layer of zinc oxide with an area of 1 cm² was formed was prepared by electrolytic deposition on one surface side of a conductive substrate of F—SnO₂ with a size of 2.0 cm in length, 1.5 cm in width, and 1.1 mm in thickness. Instead of the facing electrode, a second substrate in which a conductive layer of molybdenum (Mo) was formed was prepared by sputtering on one surface side of the conductive substrate of F—SnO₂ with the size of 2.0 cm in length, 1.5 cm in width, and 1.1 mm in thickness.

Next, the mixture of the electrolyte solution and the particle was prepared. First, tetrabutylammonium iodide (TBAI) as a solid electrolyte salt was dissolved in the organic solvent, and the electrolyte solution was adjusted. At this time, as indicated in Table 1, as the organic solvent, acetonitrile (AN; Reference example 1), methoxyacetonitrile (MAN; Reference example 2), propylnitrile (PN; Reference example 3), or butyronitrile (BN; Reference example 4) was used, and the content of TBAI in the electrolyte solution was 0.5 mol/dm³. Finally, the electrolyte solution and the particle were mixed to adjust the mixture in paste form. At this time, as the particle, commercially-available carbon black (CB; average grain diameter=13 nm, and specific surface area=310 m²/g) which was manufactured by furnace method was used, and the content of CB in the mixture was 40 weight %.

Next, the mixture was squeegeed on the metal oxide semiconductor layer in the first substrate. Then, the face where the metal oxide semiconductor layer in the first substrate was formed, and the face where the conductive layer in the second substrate was formed faced each other and were adhered with a spacer with a thickness of 50 μm to maintain a predetermined space between the first substrate and the second substrate. The spacer was placed to surround the metal oxide semiconductor layer. After that, the whole was sealed by applying commercially-available photosensitive resin as sealant with a dispenser. Thereby, the simple cell was obtained.

### Reference Examples 5 to 8

The same steps as in Reference examples 1 to 4 were taken except that the electrolyte solution with composition indicated in Table 1 is sealed between the first substrate and the second substrate. At this time, there were two holes (φ1 mm) for injecting liquid in the second substrate. The first substrate and the second substrate were adhered with a spacer in between, and the whole except the holes for injecting liquid was sealed by using commercially-available photosensitive resin with a dispenser. Then, the organic solvent was injected from the holes for injecting liquid to between the first substrate and the second substrate, and the holes were sealed with the commercially-available photosensitive resin.

In the simple cell in Reference examples 1 to 8, the durability under a high-temperature environment was investigated. The results indicated in Table 1 were obtained.

When investigating the durability, the simple cell was subjected to a high-temperature atmosphere, and a duration test was conducted. Specifically, the temperature of the simple cell in a constant-temperature bath was increased from 90° C. to 170° C. by 20° C., and presence or absence of peeling of the sealing of the cell and liquid leakage was confirmed by visual observation. In this case, it was evaluated as ⊚, when peeling of the sealing and the liquid leakage were not observed. It was evaluated as ◯, when peeling of the sealing was observed, but the liquid leakage was not observed. It was evaluated as Δ, when peeling of the sealing and liquid bleeding were observed. It was evaluated as ×, when peeling of the sealing and the liquid leakage were observed. In the case where it was evaluated as ×, the evaluation at temperature higher than that temperature when evaluated as × was not conducted.

TABLE 1

| | Electrolyte solution | | | Duration test | | | | |
|---|---|---|---|---|---|---|---|---|
| | Solid | | | (Temperature; ° C.) | | | | |
| | electrolyte salt | Organic solvent | Particle | 90 | 110 | 130 | 150 | 170 |
| Reference | TBAI | AN | CB | ◯ | ◯ | ◯ | ◯ | ◯ |
| example 1 | 0.5 mol/dm³ | | 40 | | | | | |
| Reference | | MAN | weight % | ⊚ | ⊚ | ◯ | ◯ | ◯ |
| example 2 | | | | | | | | |
| Reference | | PN | | ⊚ | ⊚ | ◯ | ◯ | ◯ |
| example 3 | | | | | | | | |
| Reference | | BN | | ⊚ | ⊚ | ⊚ | ◯ | ◯ |
| example 4 | | | | | | | | |
| Reference | TBAI | AN | — | X | — | — | — | — |
| example 5 | 0.5 mol/dm³ | | | | | | | |
| Reference | | MAN | | ⊚ | Δ | X | — | — |
| example 6 | | | | | | | | |
| Reference | | PN | | ⊚ | ⊚ | Δ | X | — |
| example 7 | | | | | | | | |
| Reference | | BN | | ⊚ | ⊚ | Δ | X | — |
| example 8 | | | | | | | | |

As indicated in Table 1, in Reference examples 1 to 4 of the case of containing the particle, the liquid leakage did not occur at any temperature. However, in Reference examples 5 to 8 of the case of not containing the particle, the liquid bleeding or leakage occurred at temperature up to 130° C. This result indicated that the particle serves as liquid retaining material for retaining the electrolyte solution.

From this, it was confirmed in the above-described simple cell that the durability improved by mixing the particle into the electrolyte solution. Therefore, it was confirmed in the above-described photoelectric conversion device that, without using particular material, the durability improved since the electrolyte containing layer 30 contained the electrolyte solution and the particle.

Next, specific examples according to the present invention will be described in detail.

### Example 1-1

As a specific example of the photoelectric conversion device described in the above embodiment, a dye-sensitized solar cell was manufactured through below steps.

First, a working electrode 10 was manufactured. A metal oxide semiconductor layer 12 of zinc oxide with an area of 1 cm² was formed by electrolytic deposition on one surface side of a conductive substrate 11 of F—SnO₂ with a size of 2.0 cm in length, 1.5 cm in width, and 1.1 mm in thickness. When forming the metal oxide semiconductor layer 12, an electrolytic bath including electrolytic bath liquid of 40 cm³, a counter electrode of a zinc plate, and a reference electrode of silver/silver chloride electrode were prepared. As the electrolytic bath, a water solution with concentration of eosin Y of 30 μmol/dm³, zinc chloride of 5 mmol/dm³, and potassium chloride of 0.09 mol/dm³ was used. The electrolytic bath was bubbled with oxygen for 15 minutes. Then, the conductive substrate 11 was dipped in the electrolytic bath which was set at temperature of 70° C. While the electrolytic bath was bubbled for 60 minutes, with constant-potential electrolysis of an electric potential of −1.0 V, zinc oxide was deposited on the surface of the conductive substrate 11. The conductive substrate 11 was dipped in potassium hydroxide water solution (pH11) without being dried, and then eosin Y was washed away. The conductive substrate 11 was dried for 30 minutes at 150° C., and thereby the metal oxide semiconductor layer 12 was formed. Finally, the conductive substrate 11 on which the metal oxide semiconductor layer 12 was formed was dipped in an ethanol solution (5 μmol/dm³) of the compound indicated in Chemical formula 1 (1) as the dye to allow the dye 13 to be carried on the metal oxide semiconductor layer 12.

Next, a facing electrode 20 was manufactured. A conductive layer 22 (100 nm in thickness) of molybdenum (Mo) was formed by sputtering on one surface side of a conductive substrate 21 of F—SnO₂ with a size of 2.0 cm in length, 1.5 cm in width, and 1.1 mm in thickness.

Next, paste for forming an electrolyte containing layer 30 was prepared. First, TBAI as a solid electrolyte salt was dissolved in methoxypropionitrile (MPN) as an organic solvent, and thus the electrolyte solution was adjusted. At this time, the content of TBAI (solid electrolyte salt) in the electrolyte solution was 0.5 mol/dm³. Finally, to obtain the paste, this electrolyte solution was added and mixed with commercially-available carbon black (CB; average grain diameter=13 nm, specific surface area=310 m²/g, and bulk resistance=10 Ωcm or less) as a carbon particle which was manufactured by furnace method. At this time, the CB was mixed with the electrolyte solution so that the content of CB in the electrolyte containing layer 30 was 5 weight %.

Next, the paste was squeegeed on the metal oxide semiconductor layer 12 carrying the dye 13 in the working electrode 10. The face carrying the dye 13 in the working electrode 10, and the face on the conductive layer 22 side of the facing electrode 20 face each other and were adhered with a spacer having a thickness of 50 μm in between. Thereby, the electrolyte containing layer 30 was formed. At this time, the spacer was placed to surround the metal oxide semiconductor layer 12. Finally, the whole was sealed, and the dye-sensitized solar cell was obtained.

### Examples 1-2 to 1-5

The same steps as in Example 1-1 were taken except that CB and the electrolyte solution were mixed and the paste was adjusted so that the content of CB in the electrolyte containing layer 30 was 10 weight % (Example 1-2), 30 weight % (Example 1-3), 40 weight % (Example 1-4), or 60 weight % (Example 1-5).

### Comparative Example 1

The same steps as in Example 1-1 were taken except that the particle was not used.

The conversion efficiency of a dye-sensitized solar cell in Examples 1-1 to 1-5 and Comparative example 1 was measured, and a relative value of the conversion efficiency in Examples 1-2 to 1-5 was investigated while regarding the conversion efficiency of Example 1-1 as 100%. The results indicated in Table 2 were obtained.

When measuring the conversion efficiency, the battery characteristics were evaluated by using a solar simulator of AM 1.5 (100 mW/m²) as a light source. Open voltage (Voc), photocurrent density (Jsc), and fill factor (FF) of the dye-sensitized solar cell were measured, and the conversion efficiency (η; %) was obtained from the values of the open voltage, and the like.

The above-described steps and conditions used for measuring the conversion efficiency were the same in subsequent Examples and Comparative examples.

TABLE 2
Conductive layer of counter electrode: Mo

| | | Electrolyte containing layer | | | |
|---|---|---|---|---|---|
| | | Electrolyte solution | | | Conversion |
| | Working | Solid | | Particle | efficiency |
| | electrode | electrolyte | Organic | (weight %) | (relative |
| | Dye | salt | solvent | CB | value; %) |
| Example 1-1 | Chemical | TBAI 0.5 mol/dm³ | MPN | 5 | 100 |
| Example 1-2 | formula 1 (1) | | | 10 | 575 |
| Example 1-3 | | | | 30 | 650 |
| Example 1-4 | | | | 40 | 925 |
| Example 1-5 | | | | 60 | 950 |
| Comparative | Chemical | TBAI 0.5 mol/dm³ | MPN | 0 | — |
| example 1 | formula 1 (1) | | | | |

As indicated in Table 2, the photoelectric conversion was performed in Examples 1-1 to 1-5 where the electrolyte containing layer 30 contained CB. However, the photoelectric conversion was not performed in Comparative example 1 where the electric containing layer 30 did not contain CB. This result indicated that CB catalyzed the redox reaction of the redox electrolyte.

In Examples 1-1 to 1-5, as the content of CB in the electrolyte containing layer 30 increased, the relative value of the conversion efficiency increased. In this case, the content of CB was 5 weight % or more and 60 weight % or less. In particular, within the range from 10 weight % to 60 weight %, there was a tendency that the conversion efficiency was high.

From this, it was confirmed that, without depending on the content of the particle, the conversion efficiency of the dye-sensitized solar cell was favorably maintained since the semi-solid electrolyte containing layer 30 contained the electrolyte solution in which at least the solid electrolyte salt was dissolved in the organic solvent, and the particle. In this case, it was confirmed that the higher conversion efficiency was obtained, when the particle content in the electrolyte containing layer 30 was 5 weight % or more and 60 weight % or less. In particular, it was confirmed that the further higher conversion efficiency was obtained, when the particle content was 10 weight % or more and 60 weight % or less.

### Examples 2-1 to 2-3

The same steps as in Example 1-4 were taken except that the content (molar concentration) of TBAI in the electrolyte solution was 0.13 mol/dm³ (Example 2-1), 0.25 mol/dm³ (Example 2-2), or 0.75 mol/dm³ (Example 2-3).

### Comparative Example 2-1

The same steps as in Comparative example 1 were taken except that the conductive layer of the counter electrode was formed with platinum, and iodine (I₂) was added to the electrolyte solution so that the content of TBAI in the electrolyte solution was 0.5 mol/dm³ and the content of I₂ was 0.05 mol/dm³.

### Comparative Example 2-2

The same steps as in Example 2-1 were taken except that, instead of the solid electrolyte salt and the organic solvent, 1-methyl-3-propyl imidazolium iodide (MPImI) being ionic liquid was used.

The conversion efficiency of the dye-sensitized solar cell in Examples 2-1 to 2-3 and Comparative examples 2-1 and 2-2 was measured, and a relative value of the conversion efficiency in Examples 2-1 to 2-3 and Comparative example 2-2 was investigated while regarding the conversion efficiency of Comparative example 2-1 as 100%. The results indicated in Table 3 were obtained. In Table 3, the relative value of the conversion efficiency in Example 1-4 was also calculated while regarding the conversion efficiency of Comparative example 2-1 as 100%. That result was also indicated.

TABLE 3
Dye of working electrode: Chemical formula 1(1)

| | Electrolyte containing layer | | | | |
|---|---|---|---|---|---|
| | Electrolyte solution | | | | Conversion |
| | Solid electrolyte | | | | efficiency |
| | salt (mol/dm³) | Organic | | | (relative |
| | TBAI | solvent | Other | Particle | value; %) |
| Example 2-1 | 0.13 | MPN | — | CB 40 | 72 |
| Example 2-2 | 0.25 | | — | weight % | 105 |
| Example 1-4 | 0.5 | | — | | 110 |
| Example 2-3 | 0.75 | | — | | 112 |
| Comparative | 0.5 | MPN | I₂ | — | 100 |
| example 2-1 | | | 0.05 mol/dm³ | | |
| Comparative | — | — | MPImI 100 | CB 40 | 53 |
| example 2-2 | | | weight % | weight % | |

As indicated in Table 3, the relative value of the conversion efficiency was 70% or more in Examples 1-4, 2-1, 2-2, and 2-3 where the electrolyte containing layer 30 contained the electrolyte solution and CB, in comparison with Comparative example 2-1 where the electrolyte containing layer 30 did not contain the particle. The relative value of the conversion efficiency was remarkably higher in Examples 1-4, 2-1, 2-2, and 2-3, in comparison with Comparative example 2-2 where the electrolyte solution was made of MPImI being ionic liquid. This result indicated that the travel of the electron in the electrolyte containing layer 30 was favorably maintained, even though CB was added to the electrolyte solution. It was considered that the conductivity was high and the electron quickly traveled in the electrolyte containing layer 30 in the case where the electrolyte solution in which the solid electrolyte salt such as TBAI was dissolved in the organic solvent such as MPN was used in comparison with the case where the ionic liquid such as MPImI was used as the electrolyte solution.

In this case, when focusing on the content of TBAI in the electrolyte solution, when the molar concentration was within the range from 0.13 mol/dm³ to 0.75 mol/dm³, the relative value of the conversion efficiency was sufficient. In particular, when the molar concentration was within the range from 0.25 mol/dm³ to 0.75 mol/dm³, the relative value of the conversion efficiency was 100% or more, and the conversion efficiency was higher in comparison with the case where the electrolyte solution with composition of the related art which did not contain a particle was used.

From this, it was confirmed that, without depending on the concentration of the solid electrolyte salt, the conversion efficiency of the dye-sensitized solar cell was favorably maintained since the semi-solid electrolyte containing layer 30 contained the electrolyte solution in which at least the solid electrolyte salt was dissolved in the organic solvent, and the particle. In this case, it was confirmed that the conversion efficiency was favorably maintained when the content (molar concentration) of the solid electrolyte salt in the electrolyte solution was within the range from 0.13 mol/dm³ to 0.75 mol/dm³, and the high conversion efficiency was obtained when the content of the solid electrolyte salt in the electrolyte solution was within the range from 0.25 mol/dm³ to 0.75 mol/dm³.

### Example 3-1

The same steps as in Example 2-1 were taken except that, when forming the electrolyte containing layer 30, instead of TBAI, tetrapropylammonium iodide (TPAI) was used as the solid electrolyte salt, and polyaniline (PA) was added as a polymer compound. Thus, the composition of the paste changed so that the content of CB was 12 weight % and the content of PA was 3 weight % in the electrolyte containing layer 30, and the content of TPAI was 0.5 mol/dm³ in the electrolyte slution. At this time, the paste was adjusted by using polyaniline carbon (CB+PA) in which CB was coated with PA as the particle (CB) and the polymer compound (PA). The bulk resistance of CB used here was 10 Ωcm or less.

### Examples 3-2 to 3-10

The same steps as in Example 3-1 were taken except that, instead of MPN, propylene carbonate (PC; Example 3-2), N-methylpyrrolidone (NMP; Example 3-3), pentanol (PNOH; Example 3-4), quinolin (QN; Example 3-5), N,N-dimethylformamide (DMF; Example 3-6), γ-butyrolactone (BL; Example 3-7), diethylene glycol monobutyl ether (DEGBE; Example 3-8), dimethyl sulfoxide (DMSO; Example 3-9), or 1,4-dioxane (DOX; Example 3-10) was used as an organic solvent.

### Comparative Example 3

The same steps as in Example 3-1 were taken except that, instead of the solid electrolyte salt and the organic solvent, MPImI being ionic liquid was used.

The conversion efficiency of a dye-sensitized solar cell in Examples 3-1 to 3-10 and Comparative example 3 was measured, and a relative value of the conversion efficiency in Examples 3-1 to 3-10 was investigated while regarding the conversion efficiency of Comparative example 3 as 100%. The results indicated in Table 4 were obtained.

TABLE 4
Conductive layer of counter electrode: Mo

| | | Electrolyte containing layer | | | | | |
|---|---|---|---|---|---|---|---|
| | | Electrolyte solution | | | | | Conversion |
| | Working | Solid | | | | | efficiency |
| | electrode | electrolyte | Organic | Ionic | | | (relative |
| | Dye | salt | solvent | liquid | Particle | Other | value; %) |
| Example 3-1 | Chemical | TPAI | MPN | — | CB 12 | PA 3 | 191 |
| Example 3-2 | formula | 0.5 mol/dm³ | PC | — | weight % | weight % | 189 |
| Example 3-3 | 1(1) | | NMP | — | | | 150 |
| Example 3-4 | | | PNOH | — | | | 131 |
| Example 3-5 | | | QL | — | | | 146 |
| Example 3-6 | | | DMF | — | | | 150 |
| Example 3-7 | | | BL | — | | | 148 |
| Example 3-8 | | | DEGBE | — | | | 120 |
| Example 3-9 | | | DMSO | — | | | 135 |
| Example 3-10 | | | DOX | — | | | 137 |
| Comparative | Chemical | — | — | MPImI | CB 12 | PA 3 | 100 |
| example 3 | formula | | | 100 | weight % | weight % | |
| | 1(1) | | | weight % | | | |

As indicated in Table 4, the relative value of the conversion efficiency was higher in Examples 3-1 to 3-10 where the electrolyte containing layer 30 contained CB and the electrolyte solution in which TPAI was dissolved in the organic solvent such as MPN, in comparison with Comparative example 3 where MPImI being ionic liquid was used as the electrolyte solution. This result indicated that the conductivity of the electrolyte containing layer 30 was higher in the case of using the electrolyte solution in which TPAI as the solid electrolyte salt was dissolved in the organic solvent in comparison with the case of using the electrolyte solution of the ionic liquid.

From this, it was confirmed that, without depending on the type of the organic solvent, the conversion efficiency of the dye-sensitized solar cell was favorably maintained since the semi-solid electrolyte containing layer 30 contained the electrolyte solution in which at least the solid electrolyte salt was dissolved in the organic solvent, and the carbon particle.

In this case, when focusing on the organic solvent, the organic solvent had a nitrile group (=MPN), a carbonate ester structure (=PC), a cyclic ester structure (=BL), a lactam structure (=NMP), an amide group (=DMF), an alcohol group (=PNOH, DEGBE), a sulfinyl group (=DMSO), pyridine ring (=QL), or a cyclic ether structure (=DOX) as a functional group. Among them, the relative value of the conversion efficiency was the highest in Example 3-1 where MPN was used as the organic solvent.

From this, it was suggested that the high conversion efficiency was obtained when the electrolyte containing layer 30 contained one or more of the above-described functional groups as the organic solvent.

### Examples 4-1 to 4-10

The same steps as in Examples 3-1 to 3-10 were taken except that, when the dye 13 was carried by the metal oxide semiconductor layer 12, the compound indicated in Chemical formula 1 (2) was used as the dye, instead of the compound indicated in Chemical formula 1 (1).

### Comparative Example 4

Similarly to Examples 4-1 to 4-10, the same steps as in Comparative example 3 were taken except that the compound indicated in Chemical formula 1 (2) was used as the dye, instead of the compound indicated in Chemical formula 1 (1).

The conversion efficiency of the dye-sensitized solar cell in Examples 4-1 to 4-10 and Comparative example 4 was measured, and the relative value of the conversion efficiency in Examples 4-1 to 4-10 was investigated while regarding the conversion efficiency of Comparative example 4 as 100%. The results indicated in Table 5 were obtained.

TABLE 5
Conductive layer of counter electrode: Mo

| | | Electrolyte containing layer | | | | | |
|---|---|---|---|---|---|---|---|
| | | Electrolyte solution | | | | | Conversion |
| | Working | Solid | | | | | efficiency |
| | electrode | electrolyte | Organic | Ionic | | | (relative |
| | Dye | salt | solvent | liquid | Particle | Other | value; %) |
| Example 4-1 | Chemical | TPAI | MPN | — | CB | PA 3 | 190 |
| Example 4-2 | formula | 0.5 mol/dm³ | PC | — | 12 | weight % | 188 |
| Example 4-3 | 1(2) | | NMP | — | weight % | | 153 |
| Example 4-4 | | | PNOH | — | | | 160 |
| Example 4-5 | | | QL | — | | | 165 |
| Example 4-6 | | | DMF | — | | | 149 |
| Example 4-7 | | | BL | — | | | 151 |
| Example 4-8 | | | DEGBE | — | | | 123 |
| Example 4-9 | | | DMSO | — | | | 151 |
| Example 4-10 | | | DOX | — | | | 132 |
| Comparative | Chemical | — | — | MPImI | CB | PA 3 | 100 |
| example 4 | formula | | | 100 | 12 | weight % | |
| | 1(2) | | | weight % | weight % | | |

As indicated in Table 5, even in the case where the dye 13 contained the compound indicated in Chemical formula 1 (2), the same results as in Table 4 were obtained. That is, in Examples 4-1 to 4-10 where the electrolyte containing layer 30 contained CB and the electrolyte solution in which TPAI was dissolved in the organic solvent such as MPN, the relative value of the conversion efficiency was higher in comparison with Comparative example 4 where MPImI being the ionic liquid was used as the electrolyte solution. The organic solvent used in this case had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 4-1 where MPN was used as the organic solvent.

### Examples 5-1 to 5-10

The same steps as in Examples 3-1 to 3-10 were taken except that, when the dye 13 was carried by the metal oxide semiconductor layer 12, the compound indicated in Chemical formula 1 (3) was used as the dye, instead of the compound indicated in Chemical formula 1 (1).

### Comparative Example 5

Similarly to Examples 5-1 to 5-10, the same steps as in Comparative example 3 were taken except that the compound indicated in Chemical formula 1 (3) was used as the dye, instead of the compound indicated in Chemical formula 1 (1).

The conversion efficiency of the dye-sensitized solar cell in Examples 5-1 to 5-10 and Comparative example 5 was measured, and the relative value of the conversion efficiency in Examples 5-1 to 5-10 was investigated while regarding the conversion efficiency of Comparative example 5 as 100%. The results indicated in Table 6 were obtained.

TABLE 6
Conductive layer of counter electrode: Mo

| | | Electrolyte containing layer | | | | | |
|---|---|---|---|---|---|---|---|
| | | Electrolyte solution | | | | | Conversion |
| | Working | Solid | | | | | efficiency |
| | electrode | electrolyte | Organic | Ionic | | | (relative |
| | Dye | salt | solvent | liquid | Particle | Other | value; %) |
| Example 5-1 | Chemical | TPAI | MPN | — | CB | PA 3 | 177 |
| Example 5-2 | formula | 0.5 mol/dm³ | PC | — | 12 | weight % | 188 |
| Example 5-3 | 1(3) | | NMP | — | weight % | | 141 |
| Example 5-4 | | | PNOH | — | | | 142 |
| Example 5-5 | | | QL | — | | | 155 |
| Example 5-6 | | | DMF | — | | | 133 |
| Example 5-7 | | | BL | — | | | 149 |
| Example 5-8 | | | DEGBE | — | | | 145 |
| Example 5-9 | | | DMSO | — | | | 140 |
| Example 5-10 | | | DOX | — | | | 133 |
| Comparative | Chemical | — | — | MPImI | CB | PA 3 | 100 |
| example 5 | formula | | | 100 | 12 | weight % | |
| | 1(3) | | | weight % | weight % | | |

As indicated in Table 6, even in the case where the dye 13 contained the compound indicated in Chemical formula 1 (3), the same results as in Table 4 were obtained. That is, in Examples 5-1 to 5-10 where the electrolyte containing layer 30 contained CB and the electrolyte solution in which TPAI was dissolved in the organic solvent such as MPN, the relative value of the conversion efficiency was higher in comparison with Comparative example 5 where MPImI being the ionic liquid was used as the electrolyte solution. The organic solvent used in this case had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 5-1 where MPN was used as the organic solvent.

### Examples 6-1 to 6-10

The same steps as in Examples 3-1 to 3-10 were taken except that, when the dye 13 was carried by the metal oxide semiconductor layer 12, the compound indicated in Chemical formula 2 (1) was used as the dye, instead of the compound indicated in Chemical formula 1 (1).

### Comparative Example 6

Similarly to Examples 6-1 to 6-10, the same steps as in Comparative example 3 were taken except that the compound indicated in Chemical formula 2 (1) was used as the dye, instead of the compound indicated in Chemical formula 1 (1).

The conversion efficiency of the dye-sensitized solar cell in Examples 6-1 to 6-10 and Comparative example 6 was measured, and the relative value of the conversion efficiency in Examples 6-1 to 6-10 was investigated while regarding the conversion efficiency of Comparative example 6 as 100%. The results indicated in Table 7 were obtained.

TABLE 7
Conductive layer of counter electrode: Mo

| | | Electrolyte containing layer | | | | | |
|---|---|---|---|---|---|---|---|
| | | Electrolyte solution | | | | | Conversion |
| | Working | Solid | | | | | efficiency |
| | electrode | electrolyte | Organic | Ionic | | | (relative |
| | Dye | salt | solvent | liquid | Particle | Other | value; %) |
| Example 6-1 | Chemical | TPAI | MPN | — | CB | PA 3 | 178 |
| Example 6-2 | formula | 0.5 mol/dm³ | PC | — | 12 | weight % | 174 |
| Example 6-3 | 2(1) | | NMP | — | weight % | | 155 |
| Example 6-4 | | | PNOH | — | | | 148 |
| Example 6-5 | | | QL | — | | | 150 |
| Example 6-6 | | | DMF | — | | | 148 |
| Example 6-7 | | | BL | — | | | 152 |
| Example 6-8 | | | DEGBE | — | | | 161 |
| Example 6-9 | | | DMSO | — | | | 151 |
| Example 6-10 | | | DOX | — | | | 140 |
| Comparative | Chemical | — | — | MPImI | CB | PA 3 | 100 |
| example 6 | formula | | | 100 | 12 | weight % | |
| | 2(1) | | | weight % | weight % | | |

As indicated in Table 7, even in the case where the dye 13 contained the compound indicated in Chemical formula 2 (1), the same results as in Table 4 were obtained. That is, in Examples 6-1 to 6-10 where the electrolyte containing layer 30 contained CB and the electrolyte solution in which TPAI was dissolved in the organic solvent such as MPN, the relative value of the conversion efficiency was higher in comparison with Comparative example 6 where MPImI being the ionic liquid was used as the electrolyte solution. The organic solvent used in this case had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 6-1 where MPN was used as the organic solvent.

### Examples 7-1 to 7-10

The same steps as in Examples 3-1 to 3-10 were taken except that, when the dye 13 was carried by the metal oxide semiconductor layer 12, the compound indicated in Chemical formula 2 (2) was used as the dye, instead of the compound indicated in Chemical formula 1 (1).

### Comparative Example 7

Similarly to Examples 7-1 to 7-10, the same steps as in Comparative example 3 were taken except that the compound indicated in Chemical formula 2 (2) was used as the dye, instead of the compound indicated in Chemical formula 1 (1).

The conversion efficiency of the dye-sensitized solar cell in Examples 7-1 to 7-10 and Comparative example 7 was measured, and the relative value of the conversion efficiency in Examples 7-1 to 7-10 was investigated while regarding the conversion efficiency of Comparative example 7 as 100%. The results indicated in Table 8 were obtained.

TABLE 8
Conductive layer of counter electrode: Mo

| | | Electrolyte containing layer | | | | | |
|---|---|---|---|---|---|---|---|
| | | Electrolyte solution | | | | | Conversion |
| | Working | Solid | | | | | efficiency |
| | electrode | electrolyte | Organic | Ionic | | | (relative |
| | Dye | salt | solvent | liquid | Particle | Other | value; %) |
| Example 7-1 | Chemical | TPAI | MPN | — | CB | PA 3 | 182 |
| Example 7-2 | formula | 0.5 mol/dm³ | PC | — | 12 | weight % | 179 |
| Example 7-3 | 2(2) | | NMP | — | weight % | | 149 |
| Example 7-4 | | | PNOH | — | | | 144 |
| Example 7-5 | | | QL | — | | | 150 |
| Example 7-6 | | | DMF | — | | | 156 |
| Example 7-7 | | | BL | — | | | 137 |
| Example 7-8 | | | DEGBE | — | | | 152 |
| Example 7-9 | | | DMSO | — | | | 159 |
| Example 7-10 | | | DOX | — | | | 147 |
| Comparative | Chemical | — | — | MPImI | CB | PA 3 | 100 |
| example 7 | formula | | | 100 | 12 | weight % | |
| | 2(2) | | | weight % | weight % | | |

As indicated in Table 8, even in the case where the dye 13 contained the compound indicated in Chemical formula 2 (2), the same results as in Table 4 were obtained. That is, in Examples 7-1 to 7-10 where the electrolyte containing layer 30 contained CB and the electrolyte solution in which TPAI was dissolved in the organic solvent such as MPN, the relative value of the conversion efficiency was higher in comparison with Comparative example 7 where MPImI being the ionic liquid was used as the electrolyte solution. The organic solvent used in this case had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 7-1 where MPN was used as the organic solvent.

### Examples 8-1 to 8-10

The same steps as in Examples 3-1 to 3-10 were taken except that, when the dye 13 was carried by the metal oxide semiconductor layer 12, the compound indicated in Chemical formula 3 (1) was used as the dye, instead of the compound indicated in Chemical formula 1 (1).

### Comparative Example 8

Similarly to Examples 8-1 to 8-10, the same steps as in Comparative example 3 were taken except that the compound indicated in Chemical formula 3 (1) was used as the dye, instead of the compound indicated in Chemical formula 1 (1).

The conversion efficiency of the dye-sensitized solar cell in Examples 8-1 to 8-10 and Comparative example 8 was measured, and the relative value of the conversion efficiency in Examples 8-1 to 8-10 was investigated while regarding the conversion efficiency of Comparative example 8 as 100%. The results indicated in Table 9 were obtained.

TABLE 9
Conductive layer of counter electrode: Mo

| | | Electrolyte containing layer | | | | | |
|---|---|---|---|---|---|---|---|
| | | Electrolyte solution | | | | | Conversion |
| | Working | Solid | | | | | efficiency |
| | electrode | electrolyte | Organic | Ionic | | | (relative |
| | Dye | salt | solvent | liquid | Particle | Other | value; %) |
| Example 8-1 | Chemical | TPAI | MPN | — | CB | PA 3 | 177 |
| Example 8-2 | formula | 0.5 mol/dm³ | PC | — | 12 | weight % | 170 |
| Example 8-3 | 3(1) | | NMP | — | weight % | | 150 |
| Example 8-4 | | | PNOH | — | | | 133 |
| Example 8-5 | | | QL | — | | | 148 |
| Example 8-6 | | | DMF | — | | | 144 |
| Example 8-7 | | | BL | — | | | 130 |
| Example 8-8 | | | DEGBE | — | | | 144 |
| Example 8-9 | | | DMSO | — | | | 136 |
| Example 8-10 | | | DOX | — | | | 136 |
| Comparative | Chemical | — | — | MPImI | CB | PA 3 | 100 |
| example 8 | formula | | | 100 | 12 | weight % | |
| | 3(1) | | | weight % | weight % | | |

As indicated in Table 9, even in the case where the dye 13 contained the compound indicated in Chemical formula 3 (1), the same results as in Table 4 were obtained. That is, in Examples 8-1 to 8-10 where the electrolyte containing layer 30 contained CB and the electrolyte solution in which TPAI was dissolved in the organic solvent such as MPN, the relative value of the conversion efficiency was higher in comparison with Comparative example 8 where MPImI being the ionic liquid was used as the electrolyte solution. The organic solvent used in this case had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 8-1 where MPN was used as the organic solvent.

From the results in Table 4 to Table 9, it was confirmed that, without depending on the type of the dye 13 and the type of the organic solvent, the conversion efficiency of the dye-sensitized solar cell was favorably maintained since the semi-solid electrolyte containing layer 30 contained the electrolyte solution in which at least the solid electrolyte salt was dissolved in the organic solvent, and the carbon particle. Moreover, it was suggested that the high conversion efficiency was obtained when the electrolyte containing layer 30 had one or more of a nitrile group, a carbonate ester structure, a cyclic ester structure, a lactam structure, an amide group, an alcohol group, a sulfinyl group, a pyridine ring, or a cyclic ether structure as a functional group.

From the results indicated in Table 1 to Table 9, in the photoelectric conversion device according to the embodiment of the present invention, it was confirmed that, without depending on the content of the particle in the electrolyte containing layer 30, the content of the solid electrolyte salt in the electrolyte solution, the type of the organic solvent and the presence or absence of the polymer compound or the like, and the type of the dye 13, the durability improved and the conversion efficiency was more favorably maintained without using particular material, since the semi-solid electrolyte containing layer 30 contained the electrolyte solution in which at least the solid electrolyte salt was dissolved in the organic solvent, and the particle. Although not disclosed in the embodiment, it was also confirmed that, similarly to the above-described results, the durability improved and the high conversion efficiency was obtained in the case where a carbon particle containing carbon material except carbon black, or other conductive particle was used as the particle. When those results and the above-described results were compared, it was suggested that higher conversion efficiency was obtained in the case where a carbon particle was used as the particle contained in the electrolyte containing layer 30. That is, it was considered that, since the carbon particle had conductivity and a function to catalyze the redox reaction, the redox reaction in the electrolyte containing layer 30 was more favorably performed, and the higher conversion efficiency was achieved in comparison with the case where a particle which did not have the catalytic function, or a particle which had an inferior catalytic function was used.

Hereinbefore, although the present invention is described with the embodiment and examples, the present invention is not limited to the aspects described in the above embodiment and examples, and various modifications may be made. For example, the application of the photoelectric conversion device according to the embodiment of the invention is not always limited to those described before, and another application is also possible. As another application, a light sensor is cited as an example.

The present application contains subject matter related to that disclosed in Japanese Priority Patent Application JP 2008-165827 filed in the Japan Patent Office on Jun. 25, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion device comprising:
an electrode including a carrying layer which carries dye; and
a semi-solid electrolyte containing layer formed on the carrying layer,
wherein the semi-solid electrolyte containing layer contains an electrolyte solution and a particle, the electrolyte solution being formed by dissolving at least a solid electrolyte salt in the organic solvent.

2. The photoelectric conversion device according to claim 1, wherein content of the particle in the electrolyte containing layer is 5 weight % or more and 60 weight % or less.

3. The photoelectric conversion device according to claim 1, wherein the particle contains carbon particles.

4. The photoelectric conversion device according to claim 3, wherein bulk resistance of the carbon particle is 10 Ωcm, i.e., 0.1 Ωm, or less.

5. The photoelectric conversion device according to claim 3, wherein carbon black is used as the carbon particle.

6. The photoelectric conversion device according to claim 1, wherein content of the solid electrolyte salt in the electrolyte solution is 0.13 mol/dm³ or more and 0.75 mol/dm³ or less.

7. The photoelectric conversion device according to claim 1, wherein the organic solvent has one or more of a nitrile group, a carbonate ester structure, a cyclic ester structure, a lactam structure, an amide group, an alcohol group, a sulfinyl group, a pyridine ring, and a cyclic ether structure as a functional group.

8. The photoelectric conversion device according to claim 1, wherein the organic solvent contains one or more of methoxypropionitrile, propylene carbonate, N-methylpyrrolidone, pentanol, quinoline, N,N-dimethylformamide, γ-butyl lactone, dimethyl sulfoxide, 1,4-dioxane, methoxyacetonitrile, and butylnitrile.

9. The photoelectric conversion device according to claim 1, wherein the solid electrolyte salt contains an iodide ion as an anion.

10. The photoelectric conversion device according to claim 1, wherein the solid electrolyte salt contains a quaternary ammonium ion as a cation.
